(19) United States
(12) Patent Application Publication
(10) Pub. No.: US 2023/0078018 A1
(43) Pub. Date: Mar. 16, 2023

(54) LAYER STRUCTURES INCLUDING CARBON-BASED MATERIAL, METHODS OF MANUFACTURING THE LAYER STRUCTURES, ELECTRONIC DEVICES INCLUDING THE LAYER STRUCTURES, AND ELECTRONIC APPARATUSES INCLUDING THE ELECTRONIC DEVICES

(71) Applicant: Samsung Electronics Co., Ltd., Suwon-si (KR)

(72) Inventors: Changseok LEE, Gwacheon-si (KR); Sangwon KIM, Seoul (KR); Kyung-Eun BYUN, Seongnam-si (KR); Minseok YOO, Suwon-si (KR)

(73) Assignee: Samsung Electronics Co., Ltd., Suwon-si (KR)

(21) Appl. No.: 17/945,534

(22) Filed: Sep. 15, 2022

(30) Foreign Application Priority Data
Sep. 16, 2021 (KR) 10-2021-0124269

(51) Int. Cl. H01L 21/265; H01L 21/02; C23C 16/02; C23C 16/26

(52) U.S. Cl. CPC H01L 21/26513; H01L 21/0228; C23C 16/0209; C23C 16/26

(57) ABSTRACT

Provided are a layer structure including a carbon-based material, a method of manufacturing the layer structure, an electronic device including the layer structure, and an electronic apparatus including the electronic device. The layer structure may include a lower layer, an ion implantation layer in the lower layer, and a carbon-based material layer on the ion implantation layer, wherein the ion implantation layer includes carbon. The ion implantation layer may include a trench, and the carbon-based material layer may be provided in the trench. The carbon-based material layer may be formed to coat an inner surface of the trench. The carbon-based material layer may fill at least a portion of the trench. The ion implantation concentration of the ion implantation layer may be uniform as a whole. The ion implantation layer may have an ion implantation concentration gradient in a given direction.

### CROSS-REFERENCE TO RELATED APPLICATION

This application is based on and claims priority under 35 U.S.C. § 119 to Korean Patent Application No. 10-2021-0124269, filed on Sep. 16, 2021 in the Korean Intellectual Property Office, the disclosure of which is incorporated by reference herein in its entirety.

### BACKGROUND

### 1. Field

The present disclosure relates to electronic apparatuses including wirings, and more particularly, to layer structures including a carbon-based material, methods of manufacturing the layer structures, electronic devices including the layer structures, and/or electronic apparatuses including the electronic devices.

### 2. Description of the Related Art

As the degree of integration of semiconductor devices has increased, the sizes of all elements constituting the semiconductor devices have decreased. The thickness of wirings connecting the elements constituting the semiconductor devices has been also reduced.

As the structures of semiconductor devices have become diversified and complicated, the deposition of a uniform thin film may be required within various pattern structures. According to continuous miniaturization processes for semiconductor circuits, in a general deposition technique, side effects, such as an overhang phenomenon and void formation, may occur inevitably when a material is deposited in a three-dimensional structure such as a trench. Accordingly, a reliability issue may be generated along with local Joule heating and electromigration.

Therefore, there may be a need for a wiring structure that overcomes these limitations, has a low resistance characteristics and may be utilized as a diffusion barrier film, a liner, etc., due to a low resistance characteristic.

### SUMMARY

Provided are layer structures including a carbon-based material that may be utilized for various purposes while ensuring low resistance characteristics.

Provided are methods of manufacturing the layer structures.

Provided are electronic devices including the layer structures.

Provided are electronic apparatuses including the electronic devices.

Additional aspects will be set forth in part in the description which follows and, in part, will be apparent from the description, or may be learned by practice of the presented embodiments of the disclosure.

According to an example embodiment, a layer structure may include a lower layer, an ion implantation layer in the lower layer, and a carbon-based material layer on the ion implantation layer. The ion implantation layer may include carbon.

In some embodiments, the ion implantation layer may include a trench, and the carbon-based material layer may be in the trench. The carbon-based material layer may be a coating on an inner surface of the trench. The carbon-based material layer may fill at least a portion of the trench. An ion implantation concentration of the ion implantation layer may be uniform in an entirety of the ion implantation layer. The ion implantation layer may have an ion implantation concentration gradient in a given direction of the ion implantation layer. The ion implantation layer may include a plurality of layers that are sequentially stacked and have different ion implantation concentrations from each other. The ion implantation concentration gradient may change continuously. The layer structure may further include an upper layer on a portion of the lower layer around the ion implantation layer. The layer structure may further include a barrier layer between the lower layer and the upper layer around the ion implantation layer.

In some embodiments, the lower layer may include a metal substrate or a semiconductor substrate.

In some embodiments, the carbon-based material layer may include a heteromaterial and carbon. The heteromaterial may include nitrogen, boron, or both nitrogen and boron. The carbon-based material layer may be a carbon compound layer including the heteromaterial. In an example, the carbon-based material layer may include a graphene layer, a layered graphene layer, an amorphous carbon layer, or a nanocrystalline graphene layer.

According to an example embodiment, a layer structure may include an ion-implantation layer including carbon; and a carbon-based material layer on a surface of the ion-implantation layer.

In some embodiments, the ion-implantation layer may be a region of a substrate surrounded by an other region of the substrate, and the carbon-based material layer may directly contact the surface of ion-implantation layer without directly contacting the other region of the substrate.

In some embodiments, the ion-implantation layer may include a trench, and the carbon-based material layer may be in the trench.

In some embodiments, the carbon-based material layer may include carbon and at least one of nitrogen and boron.

In some embodiments, the layer structure may further include a conductive plug on the carbon-based material layer. The carbon-based material layer may be between the conductive plug and the ion-implantation layer.

According to an example embodiment, a method of manufacturing a layer structure may include forming an ion implantation layer including carbon in a lower layer; and forming a carbon-based material layer on the ion implantation layer by performing a heat treatment process on the lower layer in which the ion implantation layer is formed.

In some embodiments, the method may further include forming an upper layer covering the ion implantation layer on the lower layer; and exposing the ion implantation layer by removing a portion of the upper layer.

In some embodiments, the exposing the ion implantation layer may include forming a trench to expose the ion implantation layer in the lower layer.

In some embodiments, in the forming the carbon-based material layer, the heat treatment process may include forming a coating of the carbon-based material layer on the inner surface of the trench, or the heat treatment process may include filling at least a portion of the trench with the carbon-based material layer.

In some embodiments, the forming the upper layer covering the ion implantation layer may include forming a diffusion barrier layer covering the ion implantation layer; and forming the upper layer on the diffusion barrier layer, wherein the exposing the ion implantation layer may include sequentially removing a portion of the upper layer and the diffusion barrier layer thereunder.

In some embodiments, the forming the ion implantation layer may include forming the upper layer on the lower layer, the upper layer defining a region of the lower layer; and forming the ion implantation layer by implanting carbon into the region of the lower layer defined by the upper layer. In an example, the forming the upper layer may form a trench in the region of the lower layer prior to the forming the ion implantation layer.

In some embodiments, the ion implantation layer may be formed in an entire portion of the lower layer.

In some embodiments, the ion implantation layer may have an ion implantation concentration gradient. In an example, the ion implantation concentration gradient may change continuously.

In some embodiments, the forming the ion implantation layer may include performing ion implantation at a uniform concentration in an entirety of a partial region of the lower layer.

In some embodiments the forming the carbon-based material layer may include performing a deposition process together with the performing of the heat treatment process with respect to the lower layer.

In some embodiments the deposition process may include a CVD process or an ALD process.

In some embodiments, the forming the trench to expose the ion implantation layer may be performed before the carbon-based material layer is formed.

In some embodiments, in the forming the carbon-based material layer, the heat treatment process and the deposition process may include forming a coating of the carbon-based material layer on an inner surface of the trench, or the heat treatment process and the deposition process may include filling at least a portion of the trench with the carbon-based material layer.

In some embodiments, the deposition process may include supplying a carbon source to the lower layer, and an amount of the carbon source supplied in the deposition process is less than an amount of the carbon source supplied when the carbon-based material layer is formed only by using the deposition process. In some embodiments, a heteromaterial may be supplied together with the carbon source to the lower layer. The heteromaterial may include a dopant material. In an example, the heteromaterial may be a material for forming a compound with carbon.

According to an example embodiment, an electronic device may include a data storage element; a transistor connected to a first side of the date storage element; and a conductive layer connected to a second side of the data storage element through the layer structure described above.

According to an embodiment, an electronic apparatus may include the electronic device described above.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a cross-sectional view showing a first layer structure including a carbon-based material according to an example embodiment;

FIG. 2 is a cross-sectional view illustrating a case in which an ion implantation layer extends to a full thickness of a lower layer of FIG. 1;

FIG. 3 is a cross-sectional view illustrating a case in which an ion implantation layer extends to an entire area of the lower layer in FIG. 1 and a carbon-based material layer is formed on an entire surface of the lower layer;

FIG. 4 is a cross-sectional view showing a second layer structure including a carbon-based material according to an example embodiment;

FIG. 5 is a cross-sectional view showing a third layer structure according to an example embodiment;

FIG. 6 is a cross-sectional view illustrating a fourth layer structure according to an example embodiment;

FIG. 7 is a cross-sectional view illustrating a fifth layer structure according to an example embodiment;

FIG. 8 is a cross-sectional view illustrating a case in which a diffusion barrier layer is provided between a lower layer and an upper layer in FIG. 7;

FIG. 9 is a cross-sectional view illustrating a case in which a carbon-based material layer partially fills a via hole included in an upper layer in the layer structure of FIG. 7;

FIG. 10 is a cross-sectional view illustrating a case in which the carbon-based material layer fills all via holes included in the upper layer in the layer structure of FIG. 7;

FIG. 11 shows a sixth layer structure including a carbon-based material according to an example embodiment;

FIG. 12 is a cross-sectional view illustrating a case in which a portion of a trench in FIG. 11 is filled with a carbon-based material;

FIG. 13 is a cross-sectional view illustrating a case in which an entire trench of FIG. 11 is filled with a carbon-based material;

FIG. 14 shows a seventh layer structure including a carbon-based material according to an example embodiment;

FIG. 15 is a cross-sectional view illustrating a case in which a carbon-based material layer is provided on an inner surface of a trench in the seventh layer structure of FIG. 14;

FIG. 16 is a cross-sectional view illustrating a case in which a portion of the trench in FIG. 14 is filled with a carbon-based material;

FIG. 17 is a cross-sectional view illustrating a case in which the entire trench of FIG. 14 is filled with a carbon-based material;

FIG. 18 is a cross-sectional view illustrating an eighth layer structure including a carbon-based material according to an example embodiment;

FIG. 19 is a cross-sectional view illustrating a case in which a diffusion barrier layer is further provided between first and second substrates of FIG. 18;

FIG. 20 is a cross-sectional view illustrating a case in which a portion of the trench in FIG. 18 is filled with a carbon-based material layer;

FIG. 21 is a cross-sectional view illustrating a case in which the entire trench of FIG. 18 is filled with a carbon-based material layer;

FIGS. 22A to 31 are cross-sectional views illustrating methods of manufacturing a layer structure including a carbon-based material according to some example embodiments;

FIG. 32A is a cross-sectional view illustrating an electronic device (e.g., memory device) including a layer structure according to an example embodiment;

FIG. 32B is a circuit diagram of inverter according to an embodiment;

FIG. 33 is a schematic block diagram of a display driver IC (DDI) having an electronic device including a layer structure according to an example embodiment and a display device including the DDI;

FIG. 34 is a block diagram of an electronic system including an electronic device including a layer structure according to an example embodiment; and

FIG. 35 is a block diagram of an electronic system including an electronic device including a layer structure according to an example embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

Hereinafter, layer structures including a carbon-based material, manufacturing methods thereof, electronic devices including the layer structure, and/or electronic apparatuses including the electronic devices, according to example embodiments will be described in detail with reference to the accompanying drawings. In the drawings, thicknesses of layers and regions may be exaggerated for clarification of the specification. The embodiments of inventive concepts are capable of various modifications and may be embodied in many different forms. When an element or layer is referred to as being “on” or “above” another element or layer, the element or layer may be directly on another element or layer or intervening elements or layers. In the descriptions below, like reference numerals refer to like elements.

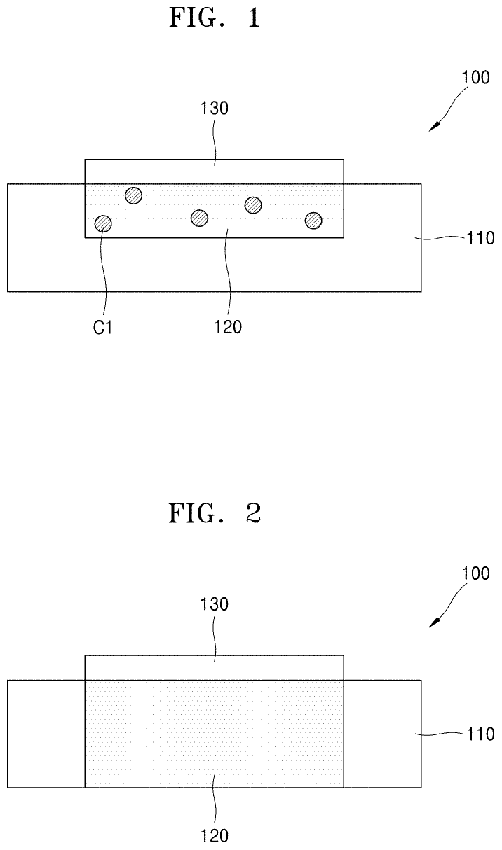

FIG. 1 shows a first layer structure 100 including a carbon-based material according to an example embodiment.

Referring to FIG. 1, the first layer structure 100 has a lower layer 110, an ion implantation layer 120 in the lower layer 110, and a carbon-based material layer 130 on the ion implantation layer 120 of the lower layer 110. The lower layer 110, the ion implantation layer 120, and the carbon-based material layer 130 are sequentially stacked in a given direction. In one example, the given direction may be a direction perpendicular to or substantially perpendicular to one surface of the lower layer 110. In one example, one surface of the lower layer 110 may be an upper surface, a side surface, a lower surface, or a surface sharing two surfaces of the lower layer 110. In one example, the lower layer 110 may include a semiconductor substrate or a substrate exhibiting semiconductor characteristics. In one example, the semiconductor substrate may be a silicon (Si) substrate or a germanium (Ge) substrate, but is not limited thereto. In an example, the semiconductor substrate may include a compound semiconductor. In one example, the lower layer 110 may be a metal layer including a first metal or a metal substrate. In one example, the first metal does not include copper (Cu), nickel (Ni), iridium (Ir), ruthenium (Ru), or platinum (Pt), and may include a metal suitable for growing the carbon-based material layer 130. In one example, the first metal may include an alloy. The ion implantation layer 120 may be a region in which at least carbon ions are implanted into a partial region of the lower layer 110. In one example, the ion implantation layer 120 may include carbon (C1) implanted by an ion implantation method. In one example, the carbon concentration of the ion implantation layer 120 may be in a range from about 1×10¹²/cm² to about 1×10¹⁸/cm². In this range, a carbon concentration of the ion implantation layer 120 before the carbon-based material layer 130 is formed may be greater than the carbon concentration of the ion implantation layer 120 after the carbon-based material layer 130 is formed.

In an example, an element (e.g., a heteromaterial) other than carbon may be included in the ion implantation layer 120. For example, nitrogen (N) and/or boron (B) may be included in the ion implantation layer 120. The ion implantation layer 120 may be a layer used to supply all or a part of a source material (e.g., carbon) required to form the carbon-based material layer 130 in a process of forming the first layer structure 100. In addition, when the ion implantation layer 120 includes the heteromaterial, in the process of forming the first layer structure 100, a part or all of the heteromaterial may be supplied from the ion implantation layer 120 to the carbon-based material layer 130. Accordingly, as an example, the carbon-based material layer 130 may include nitrogen and/or boron as dopants, but is not limited thereto. By including nitrogen and/or boron in the carbon-based material layer 130, electrical properties of the carbon-based material layer 130 may be adjusted. In one example, the carbon-based material layer 130 may be a carbon compound layer including nitrogen and/or boron or may include the carbon compound layer. When the carbon-based material layer 130 includes a carbon compound, an amount of nitrogen and/or boron included may be greater than an amount implanted as a dopant. In one example, the concentration of nitrogen and/or boron in the carbon-based material layer 130 may be in a range from about 1×10¹²/cm² to about 1×10¹⁸/cm². In one example, the carbon-based material layer 130 may include an amorphous carbon layer, a graphene layer, a layered graphene layer, or a nanocrystalline graphene layer.

Because the first layer structure 100 of FIG. 1 may serve as a transmission path of an electrical signal between two elements constituting an electronic device or an electronic system, it may be expressed as “wiring”, “wiring layer structure” or “wiring structure”. Layer structures described as being below other elements may be also considered as being above the elements.

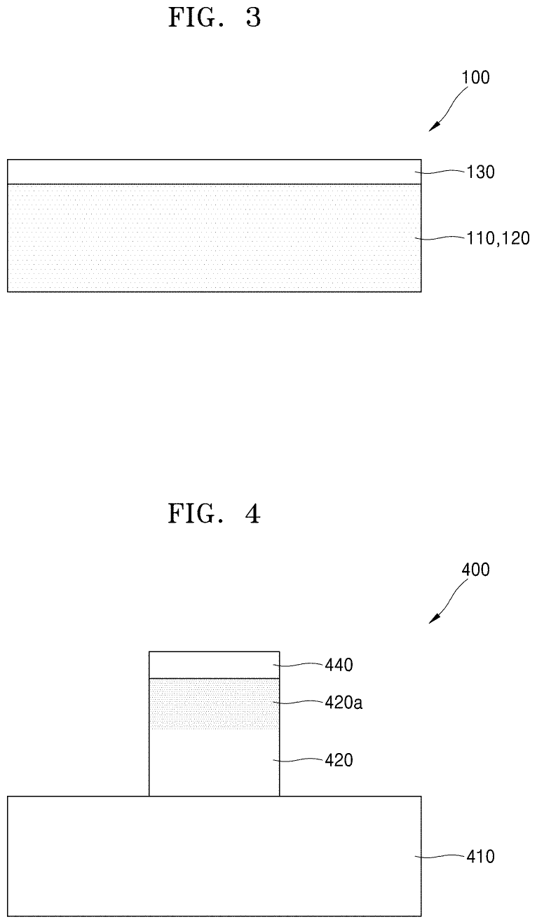

In one example, as shown in FIG. 2, the ion implantation layer 120 may be formed in an entire thickness of the lower layer 110 at a position where the ion implantation layer 120 is formed. Also, in one example, as shown in FIG. 3, the ion implantation layer 120 may be the entire lower layer 110, and the carbon-based material layer 130 may be formed on an entire upper surface of the lower layer 110.

FIG. 4 shows a second layer structure 400 according to an example embodiment.

Referring to FIG. 4, a first material layer 420 is present on a partial region of one surface of a substrate 410. The one surface may be an upper surface, a side surface, or a lower surface of the substrate 410. In one example, the substrate 410 may include an insulating substrate. The first material layer 420 may protrude in a direction perpendicular to the one surface of the substrate 410, and an aspect ratio may be less than 1, 1 or greater than 1. The first material layer 420 may include an ion implantation layer 420a. The ion implantation layer 420a is separated from the one surface of the substrate 410. The ion implantation layer 420a may be a region corresponding to an upper portion of the first material layer 420. The material of the first material layer 420 may include or be the same as the material of the lower layer 110 of FIG. 1. The ion implantation layer 420a may correspond to the ion implantation layer 120 of FIG. 1. That is, characteristics related to doping and material of the ion implantation layer 420a may be the same as those of the ion implantation layer 120 of FIG. 1. A carbon-based material layer 440 is provided on one surface of the first material layer 420 parallel to the upper surface of the substrate 410. The carbon-based material layer 440 may be provided on the ion implantation layer 420a and may be in contact with the ion implantation layer 420a. A width of the carbon-based material layer 440 in a direction parallel to the substrate 410 may be the same as that of the first material layer 420.

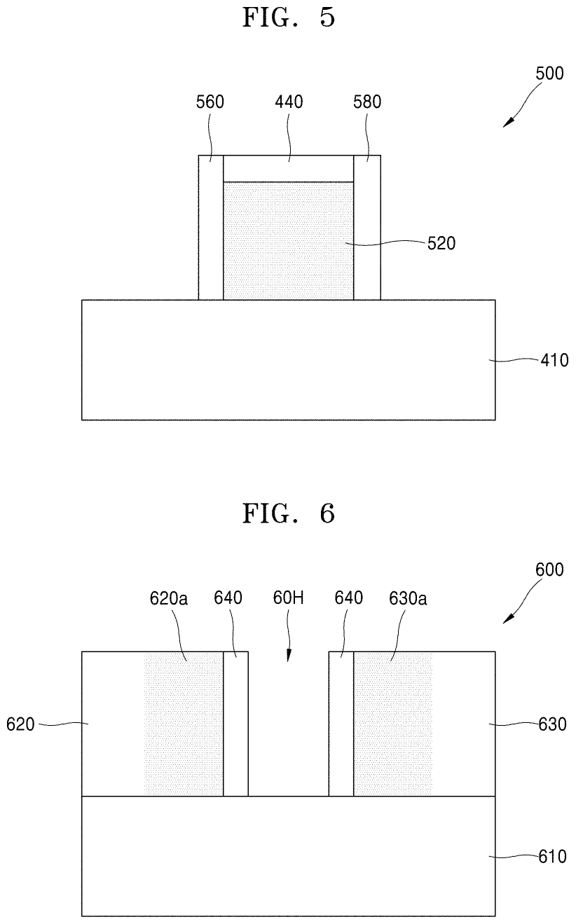

FIG. 5 shows a third layer structure 500 according to an example embodiment. Only parts different from the second layer structure 400 of FIG. 4 will be described.

Referring to FIG. 5, the third layer structure 500 includes an ion implantation layer 520 on a substrate 410, and carbon-based material layers 440, 560, and 580 on side and upper surfaces of the ion implantation layer 520. The ion implantation layer 520 may correspond to a case when, in the second layer structure 400 of FIG. 4, the ion implantation layer 420a extends to the entire first material layer 420, that is, carbon is implanted in the entire first material layer 420. In one example, the material and configuration of the carbon-based material layers 560 and 580 provided on both side surfaces of the ion implantation layer 520 may be the same as those of the carbon-based material layer 130 of FIG. 1.

FIG. 6 shows a fourth layer structure 600 according to an example embodiment.

Referring to FIG. 6, the fourth layer structure 600 includes a substrate 610 and first and second material layers 620 and 630 provided on the substrate 610 and separated from each other. Heights of the first and second material layers 620 and 630 may be equal to each other. The material of the substrate 610 may be the same as that of the substrate 410 of FIG. 4. The first material layer 620 includes a first ion implantation layer 620a, and the second material layer 630 includes a second ion implantation layer 630a. Materials of the first and second material layers 620 and 630 may be the same as those of the lower layer 110 of the first layer structure 100 of FIG. 1. The first and second ion implantation layers 620a and 630a may be arranged parallel to each other. The first ion implantation layer 620a is formed from the right side of the first material layer 620 to the left side thereof, and is separated from the left side of the first material layer 620. The second ion implantation layer 630a is formed from the left side of the second material layer 630 to the right side thereof, and is separated from the right side of the second material layer 630.

The first ion implantation layer 620a may be parallel to a right surface of the first material layer 620. In one example, the first ion implantation layer 620a may extend to an entire first material layer 620. That is, the entire first material layer 620 may be an ion implantation layer.

The second ion implantation layer 630a may be parallel to a left surface of the second material layer 630. In one example, the second ion implantation layer 630a may extend to an entire second material layer 630. That is, the entire second material layer 630 may be an ion implantation layer.

Descriptions related to ion implantation and materials of the first and second ion implantation layers 620a and 630a may be the same as those of the ion implantation layer 120 of the first layer structure 100 of FIG. 1. Each carbon-based material layer 640 is provided on the right side of the first material layer 620 and the left side of the second material layer 630, respectively. The carbon-based material layer 640 may directly contact the right side of the first material layer 620 and the left side of the second material layer 630. A height of the carbon-based material layer 640 in a direction perpendicular to the substrate 610 may be the same as that of the first and second material layers 620 and 630. The carbon-based material layers 640 are separated from each other in a direction horizontal to an upper surface of the substrate 610. A via hole 60H, which is a space between the separated carbon-based material layers 640, may be filled with another material (e.g., a conductive material). The material of the carbon-based material layer 640 may be the same as that of the carbon-based material layer 130 of FIG. 1.

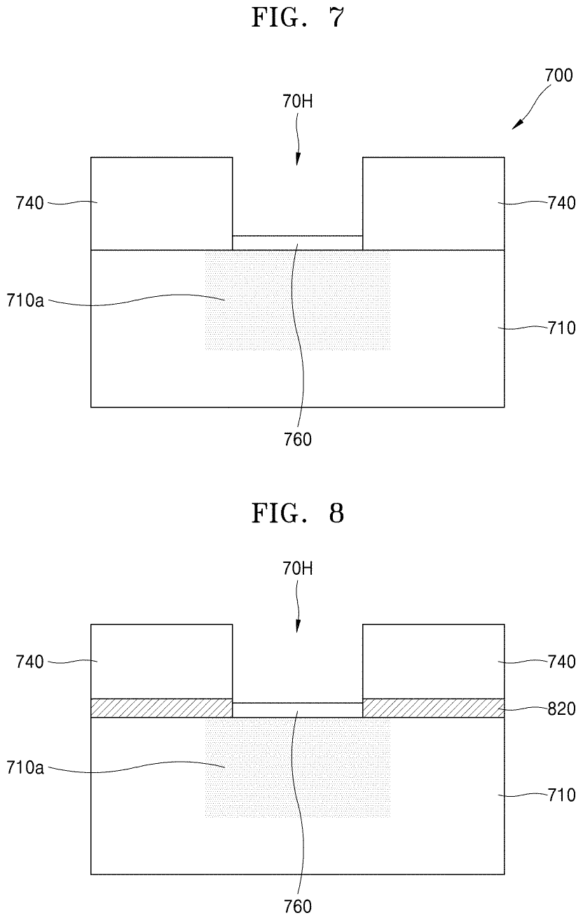

FIG. 7 shows a fifth layer structure 700 according to an example embodiment.

Referring to FIG. 7, a lower layer 710 includes an ion implantation layer 710a. The material and configuration of the lower layer 710 may be the same as those of the lower layer 110 of FIG. 1. Descriptions related to ion implantation and material of the ion implantation layer 710a may be the same as those of the ion implantation layer 120 of FIG. 1. Each upper layer 740 is arranged on the lower layer 710 to be separated from each other. The ion implantation layer 710a may be exposed through a region between the separated upper layers 740, that is, a via hole 70H. In one example, the ion implantation layer 710a may extend to an entire area of the lower layer 710. In one example, in FIG. 7, the ion implantation layer 710a may extend to a lower surface of the lower layer 710. In one example, a material of the upper layer 740 may be the same as or different from that of the lower layer 710. In one example, the upper layer 740 may be or include an insulating layer. In one example, the upper layer 740 may be a mask (e.g., a photoresist pattern) used in a semiconductor photolithography process. A carbon-based material layer 760 is present on the ion implantation layer 710a exposed through the via hole 70H. The carbon-based material layer 760 may cover an entire exposed surface of the ion implantation layer 710a exposed through the via hole 70H, and may be provided in the form of a film in direct contact with the surface. The carbon-based material layer 760 may be in direct contact with the upper layer 740. The material and configuration of the carbon-based material layer 760 may be the same as that of the carbon-based material layer 130 of FIG. 1.

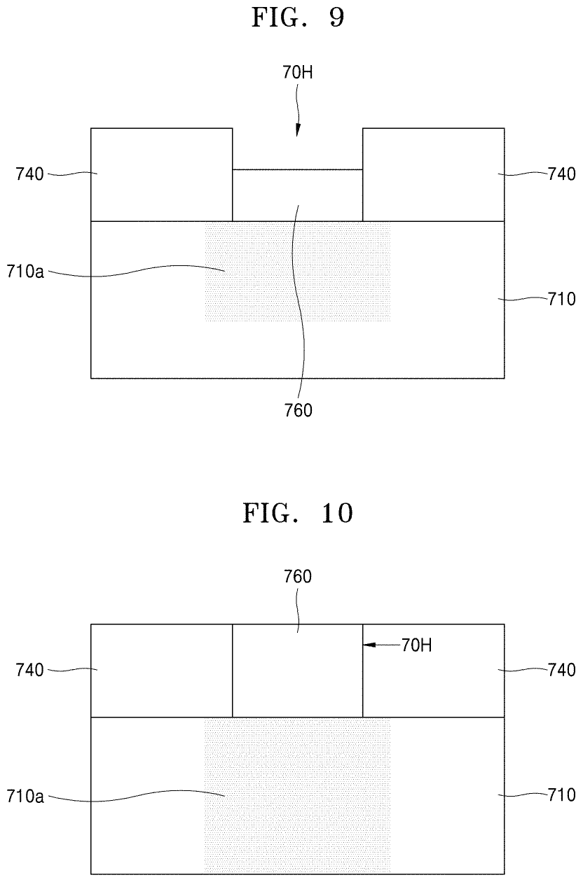

In an example embodiment, the fifth layer structure 700 may further include a barrier layer 820 between the lower layer 710 and the upper layer 740, as shown in FIG. 8. Because the barrier layer 820 is provided, diffusion of carbon or excessive diffusion of carbon from the ion implantation layer 710a to the upper layer 740 may be prevented. In one example, the barrier layer 820 is a diffusion barrier layer, and may be or include a TiN layer or a TaN layer. Also, in an example embodiment, the carbon-based material layer 760 of the fifth layer structure 700 may be provided to partially fill the via hole 70H, as shown in FIG. 9. Also, in one embodiment, the carbon-based material layer 760 of the fifth layer structure 700 may be provided to fill the entirety of the via hole 70H, as shown in FIG. 10.

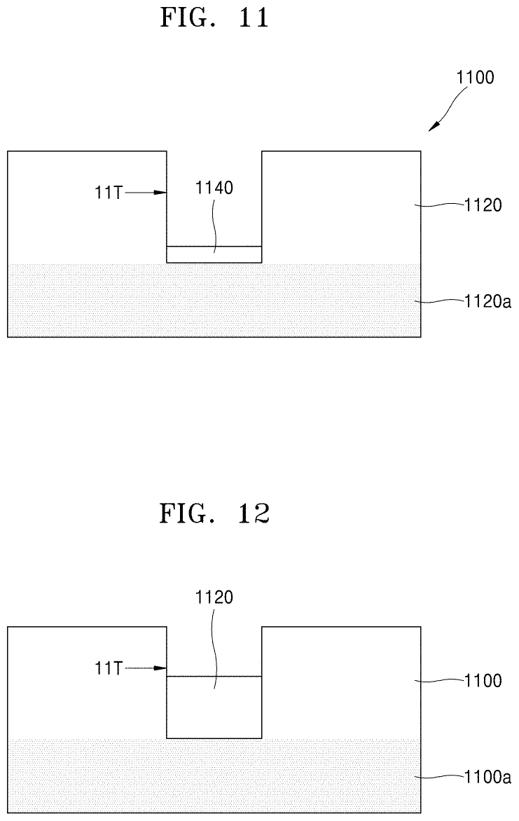

FIG. 11 shows a sixth layer structure 1100 including a carbon-based material according to an example embodiment.

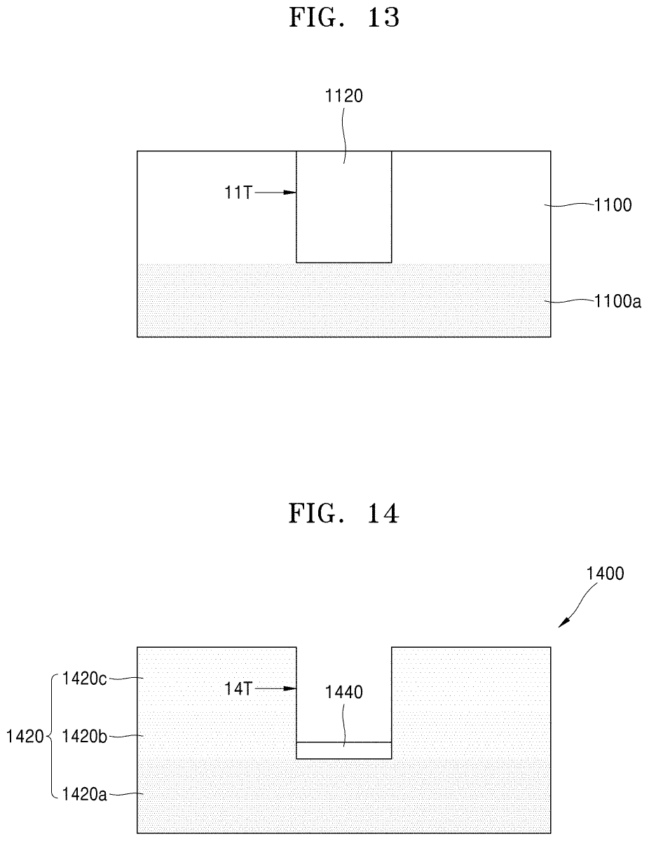

Referring to FIG. 11, the sixth layer structure 1100 includes a substrate 1120, an ion implantation layer 1120a formed in the substrate 1120, and a trench 11T formed in the substrate 1120. The ion implantation layer 1120a is formed on a lower layer part of the substrate 1120. That is, the ion implantation layer 1120a corresponds to the lower layer part of the substrate 1120, and is formed up to a given distance from a lower surface of the substrate 1120. The ion implantation layer 1120a is parallel to the lower surface of the substrate 1120 and separated from an upper surface of the substrate 1120. The material and configuration of the substrate 1120 may be the same as that of the lower layer 110 of FIG. 1. Descriptions related to ion implantation and materials of the ion implantation layer 1120a may be the same as those of the ion implantation layer 120 of FIG. 1. However, the ion implantation concentration of the ion implantation layer 1120a may be greater than that of the ion implantation layer 120 of FIG. 1. The trench 11T may be formed to a given depth downward from the upper surface of the substrate 1120, and a bottom of the trench 11T may be the ion implantation layer 1120a. That is, the trench 11T may be formed by etching a partial region of the substrate 1120 until the ion implantation layer 1120a is exposed. A carbon-based material layer 1140 covering the bottom of the trench 11T is provided in the trench 11T. The carbon-based material layer 1140 may cover an entire bottom of the trench 11T and may be provided in the form of a film in direct contact with the bottom. In one example, as shown in FIG. 12, a portion of the trench 11T may be filled with the carbon-based material layer 1120. In one example, as shown in FIG. 13, the entire trench 11T may be filled with the carbon-based material layer 1120.

FIG. 14 shows a seventh layer structure 1400 including a carbon-based material according to an example embodiment.

Referring to FIG. 14, the seventh layer structure 1400 includes a substrate 1420 including first to third ion implantation layers 1420a, 1420b, and 1420c. The substrate 1420 includes a trench 14T. The material of the substrate 1420 may be the same as that of the lower layer 110 of FIG. 1. The first to third ion implantation layers 1420a, 1420b, and 1420c fill the entire substrate 1420, and are sequentially formed from a lower surface to an upper surface of the substrate 1420. Although the substrate 1420 is illustrated as including the first to third ion implantation layers 1420a, 1420b, and 1420c, the substrate 1420 may include three or more ion implantation layers. In one example, the ion implantation concentrations of the first to third ion implantation layers 1420a, 1420b, and 1420c may be different from each other. For example, the ion implantation concentration of the first ion implantation layer 1420c formed at the bottom may be the greatest, and the ion implantation concentration of the third ion implantation layer 1420c formed at the top may be the least. The second ion implantation layer 1420b may have an ion implantation concentration between the first and third ion implantation layers 1420a and 1420c. In this way, the substrate 1420 may include an ion implantation layer 1420a+1420b+1420c having an ion implantation concentration gradient between two surfaces (e.g., an upper surface and a lower surface). In one example, the substrate 1420 may include an ion implantation layer in which an ion implantation concentration gradient continuously changes from the lower surface to the upper surface. Descriptions related to ion implantation and materials of the first to third ion implantation layers 1420a, 1420b, and 1420c may be the same as those of the ion implantation layer 120 of FIG. 1. The trench 14T is formed at a given depth from the upper surface toward the lower surface of the substrate 1420. The trench 14T may be formed to sequentially penetrate the third and second ion implantation layers 1420c and 1420b, and the bottom of the trench 14T may serve as a first ion implantation layer 1420a. The bottom of the trench 14T is covered with a first carbon-based material layer 1440. The first carbon-based material layer 1440 may cover an entire bottom of the trench 14T and may be in direct contact with the bottom of the trench 14T. The first carbon-based material layer 1440 is provided in the form of a film covering the entire bottom of the trench 14T.

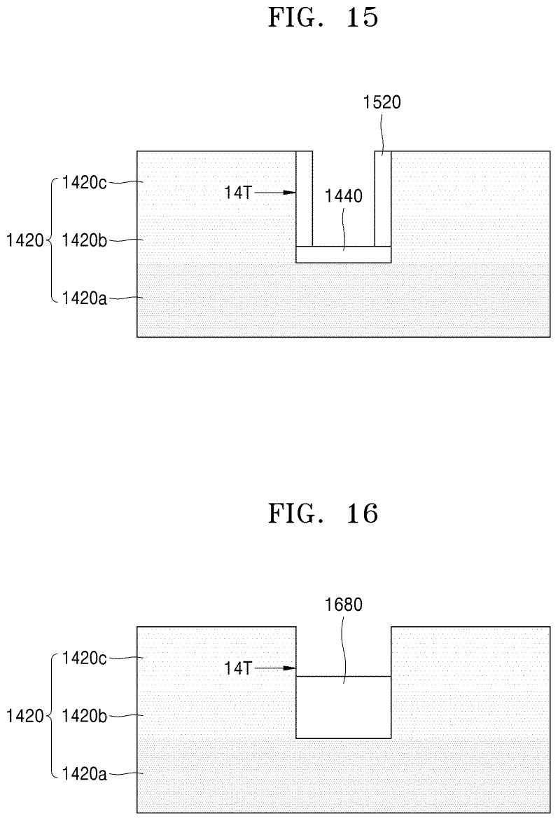

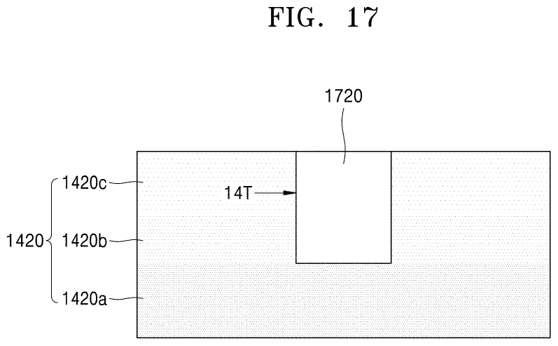

In one embodiment, as shown in FIG. 15, the seventh layer structure 1400 may include a second carbon-based material layer 1520 covering an inner surface of the trench 14T. The second carbon-based material layer 1520 may cover the entire inner surface of the trench 14T and may be in direct contact with the inner surface thereof. The material of the second carbon-based material layer 1520 may be the same as that of the first carbon-based material layer 1440. In an example embodiment, as shown in FIG. 16, in the seventh layer structure 1400, a portion of the trench 14T may be filled with a carbon-based material layer 1680. In an example embodiment, as shown in FIG. 17, in the seventh layer structure 1400, the entire trench 14T may be filled with a carbon-based material layer 1720. The material of the carbon-based material layers 1680 and 1720 may be the same as that of the carbon-based material layer 130 of FIG. 1.

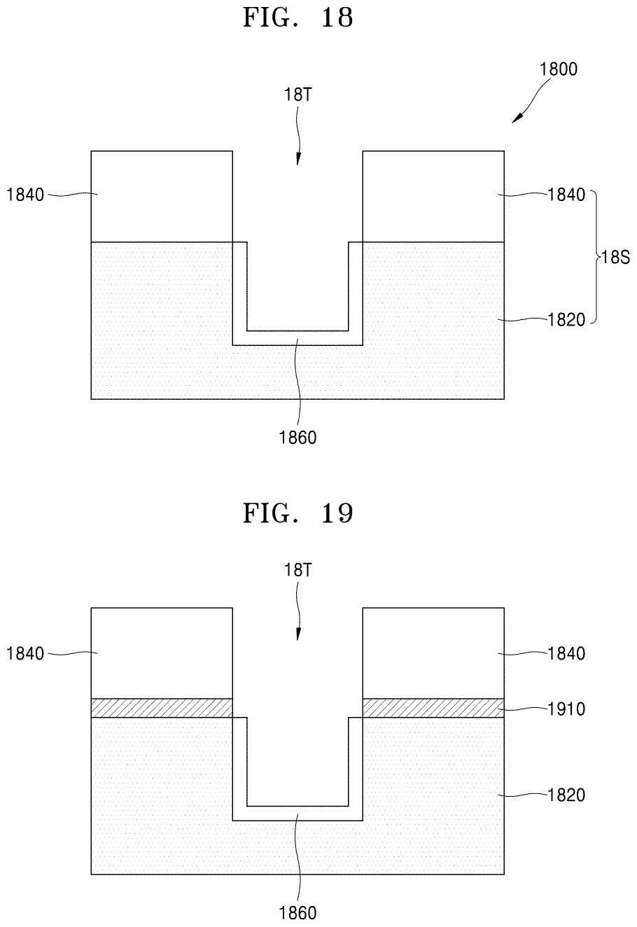

FIG. 18 shows an eighth layer structure 1800 including a carbon-based material according to an example embodiment.

Referring to FIG. 18, the eighth layer structure 1800 includes first and second substrates 1820 and 1840 sequentially stacked. A trench 18T is formed in a stack 18S including the first and second substrates 1820 and 1840. The trench 18T penetrates through the second substrate 1840 and is formed from an upper surface of the first substrate 1820 down to a given depth. A bottom of the trench 18T is separated from a bottom of the first substrate 1820. The entire first substrate 1820 is an ion implantation layer, and may correspond to the lower layer 110 of FIG. 1. Contents related to ion implantation of the first substrate 1820 (e.g., implantation material, concentration, etc.) may be the same as that of the ion implantation layer 120 of FIG. 1. The material of the second substrate 1840 may be the same as or different from that of the first substrate 1820. The second substrate 1840 may perform a role of protecting a surface damage of the first substrate 1820. In one example, the second substrate 1840 may be an insulating substrate (e.g., SiN) or a mask (e.g., a photoresist film) used in a semiconductor manufacturing process. A carbon-based material layer 1860 is provided inside the trench 18T. The carbon-based material layer 1860 is provided to cover the bottom of the trench 18T and an entire inner surface of the first substrate 1820 that is in the trench 18T. The carbon-based material layer 1860 may be in contact with the bottom of the trench 18T and the inner surface of the first substrate 1820. The material and configuration of the carbon-based material layer 1860 may be the same as that of the carbon-based material layer 130 of FIG. 1. In one embodiment, in the eighth layer structure 1800, as shown in FIG. 19, a diffusion barrier layer 1910 that limits, minimizes or prevents diffusion of carbon is provided between the first substrate 1820 and the second substrate 1840. The material of the diffusion barrier layer 1910 may be the same as the material of the barrier layer 820 of FIG. 8.

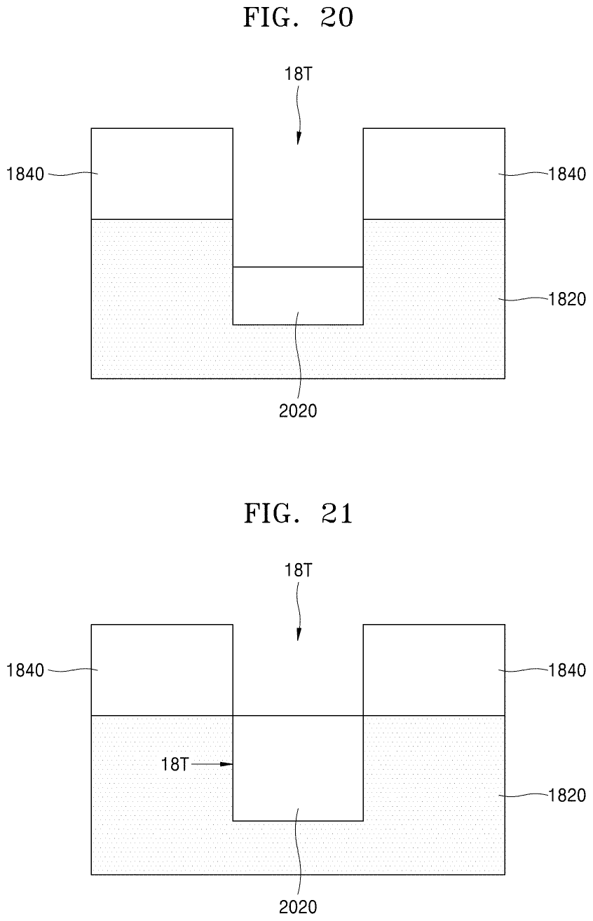

In an example embodiment, as shown in FIG. 20, in the eighth layer structure 1800, a portion of the trench 18T may be filled with a carbon-based material layer 2020. The material and configuration of the carbon-based material layer 2020 may be the same as that of the carbon-based material layer 130 of FIG. 1. The carbon-based material layer 2020 may fill the entire trench 18T as shown in FIG. 21.

The carbon-based material layer described in the layer structure according to the embodiment described above may be utilized as a diffusion barrier layer and/or a liner, etc. depending on the provided position.

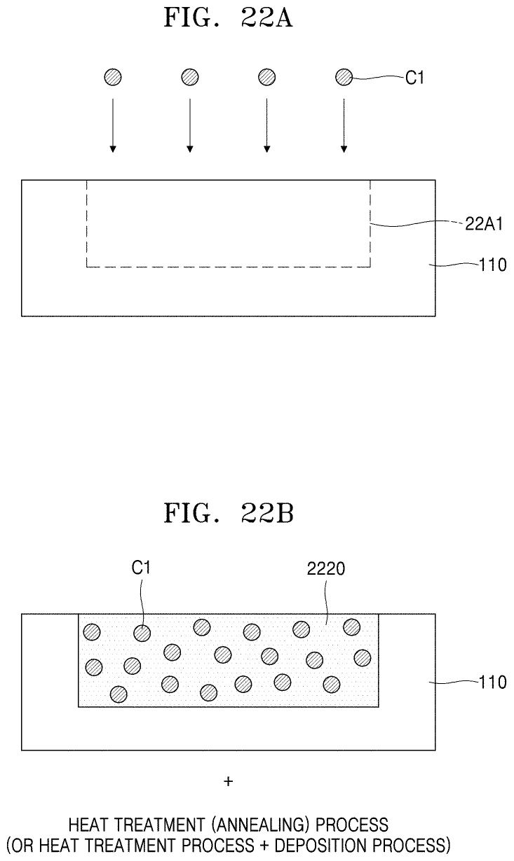

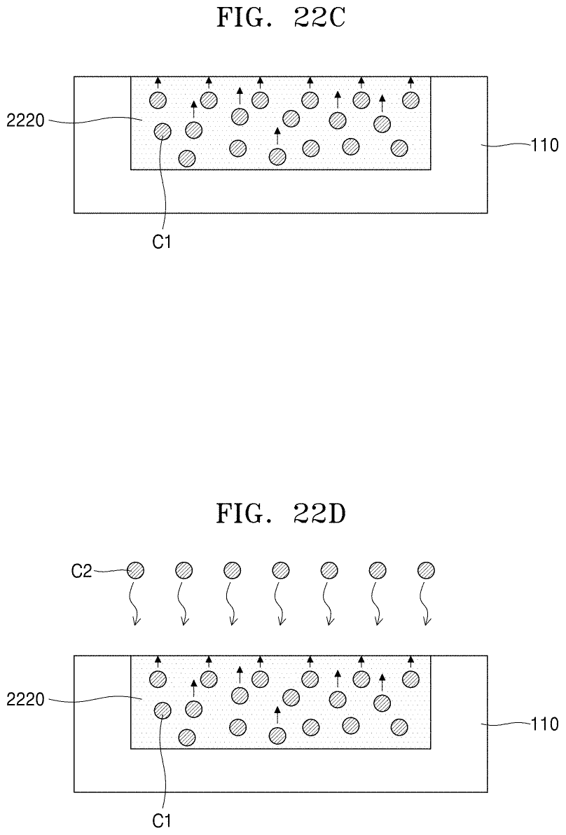

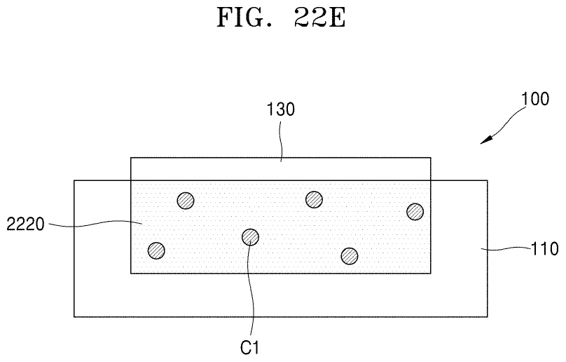

Next, a method of manufacturing a layer structure including a carbon-based material according to some example embodiments will be described with reference to FIGS. 22 to 31. The same reference numerals as the aforementioned reference numerals indicate the same members, and detailed descriptions thereof will be omitted.

FIGS. 22A to 22E show a manufacturing process of the first layer structure 100 according to an example embodiment.

First, as shown in FIG. 22A, a first material C1 is injected into a set region 22A1 of the lower layer 110. In one example, the first material C1 may be implanted by using an ion implantation method. In one example, the first material C1 may be a carbon ion or may include a carbon ion. As a result of ion implantation of the first material C1, as shown in FIG. 22B, a layer 2220 to which ions are implanted (hereinafter, referred to as an ion implantation layer 2220) is formed in the lower layer 110. In one example, an amount or density of the first material C1 included in the ion implantation layer 2220 may exceed a doping level. In one example, when the first material C1 is carbon, an implantation concentration of carbon ions implanted to form the ion implantation layer 2220 may be in a range from about 1×10¹²/cm² to about 1×10¹⁸/cm². In one example, a carbon source used to form the ion implantation layer 2220 may include hydrocarbon (e.g., CH₄) or acetylene (C₂H₂). The ion implantation layer 2220 may be formed to have a given depth from the upper surface to the lower surface of the lower layer 110. In one example, the ion implantation layer 2220 may be formed up to the lower surface of the lower layer 110. In one example, the ion implantation layer 2220 may be formed on the entire lower layer 110.

In an example, in the process of ion implantation of the first material C1 of FIG. 22A, the first material C1 may be implanted together with a heteromaterial. In this case, the ion implantation layer 2220 may include the heteromaterial together with the first material C1. In an example, the heteromaterial may include a plurality of materials different from the first material C1. For example, in the ion implantation process, a first heteromaterial may be implanted together with the first material C1. For example, in the ion implantation process, a second heteromaterial different from the first heteromaterial may be implanted together with the first material C1. For example, in the ion implantation process, first and second heteromaterials may be implanted together with the first material C1. In the process of ion implantation of the first and/or second heteromaterials together with the first material C1, an ion implantation amount of the first heteromaterial and the second heteromaterial are less than an ion implantation amount of the first material C1.

In one example, the ion implantation amount of each of the first and second heteromaterials corresponds to an amount not forming a compound with the first material C1 in the finally formed carbon-based material layer (130 in FIG. 22E), and it may be an amount corresponding to doping or a dopant amount.

In one example, the ion implantation amount of each of the first heteromaterial and the second heteromaterial may correspond to an amount capable of forming a compound with the first material C1 in the finally formed carbon-based material layer 130.

In one example, the first heteromaterial may include nitrogen (N). In one example, the second heteromaterial may include boron (B).

As described above, after the ion implantation layer 2220 is formed, a heat treatment (annealing) process may be performed on a resultant product, that is, the lower layer 110 on which the ion implantation layer 2220 is formed. The heat treatment process may be performed at a temperature in a range of about 100° C. to about 1,000° C. for a given time. In one example, the given time may be in a range from about 1 second to 180 minutes. The first material (e.g., carbon) included in the ion implantation layer 2220, as shown in FIG. 22C, is transferred to a surface of the ion implantation layer 2220 through external diffusion by the heat treatment process, and as a result, as shown in FIG. 22E, the carbon-based material layer 130 is formed on the ion implantation layer 2220. In one example, as the first material C1 is externally diffused from the ion implantation layer 2220 to form the carbon-based material layer 130, the first material C1 in a doping level may remain in the ion implantation layer 2220 after the carbon-based material layer 130 is formed. Accordingly, the ion implantation layer 2220 after the carbon-based material layer 130 is formed may be regarded as a doping layer.

In one example, when the first and/or the second heteromaterial is present together with the first material C1 in the ion implantation layer 2220, when the first material C1 is diffused, the first and/or the second heteromaterial may also be externally diffused. Depending on the degree of external diffusion of the first and/or second heteromaterial, the carbon-based material layer 130 may be a carbon-based material layer including the first and/or second heteromaterial as a dopant, or may be a carbon compound layer including the first and/or second heteromaterial.

In one example, the heat treatment process may be performed under a condition that the carbon-based material layer 130 forms a coating (e.g., a thin film) on one surface of the ion implantation layer 2220.

In one example, after the ion implantation layer 2220 is formed, a deposition process may be simultaneously performed with the heat treatment process with respect to a resultant product, that is, the lower layer 110 on which the ion implantation layer 2220 is formed. In one example, the deposition process may be performed by using a chemical vapor deposition (CVD) method or an atomic layer deposition (ALD) method in consideration of the carbon-based material layer to be formed. The carbon source may be used in the deposition process. In one example, the heat treatment process and the deposition process may be performed under a condition that the carbon-based material layer is in the form of coating a surface of the ion implantation layer 130.

The deposition process may include supplying a second material C2 to the lower layer 110 as shown in FIG. 22D. The second material C2 may be supplied to cover an exposed surface of the ion implantation layer 2220. In an example, the second material C2 may include carbon or a carbon source.

In one example, an amount of the second material C2 supplied to the lower layer 110 which is loaded in a chamber (not shown) in the deposition process may be less than an amount of the second material C2 supplied when the carbon-based material layer 130 is formed only through the deposition process. When the deposition process is used together, an amount of the first material C1 implanted into the lower layer 110 to form the ion implantation layer 2220 may be less than when the carbon-based material layer 130 is formed by using only the ion implantation layer 2220.

In an example, in the deposition process, the first and/or second heteromaterial may also be supplied together with the second material C2.

As shown in FIG. 22D, the second material C2 including carbon is supplied to the lower layer 110 from the outside of the lower layer 110 by the deposition process, and at the same time, internally, the first material C1 is externally diffused from the ion implantation layer 2220 by the heat treatment process. As a result, the carbon-based material layer 130 as shown in FIG. 22E may be formed on the ion implantation layer 2220. When the first and/or second heteromaterial is included in the ion implantation layer 2220 and the first and/or second heteromaterial is also included in the deposition process, depending on an amount of the first and/or second heteromaterial externally diffused from the ion implantation layer 2220 and an amount of the first and/or second heteromaterial supplied together with the second material C2 in the deposition process, the carbon-based material layer 130 may be a layer to which the first and/or second heteromaterial is doped or may be a carbon compound layer or a carbon-based compound layer.

In one example, even when the heat treatment process and the deposition process are used together, similar to the case when only the heat treatment process is used, the first material C1 only at a doping level may remain in the ion implantation layer 2220 after the carbon-based material layer 130 is formed. Therefore, the ion implantation layer 2220 after the carbon-based material layer 130 is formed may be referred to as a doping layer.

There is no limitation on a surface or pattern to which the method described above may be applied. That is, the method described above may be applied not only to a flat surface, but also to a surface of a curved surface that is not flat or a pattern (e.g., the trenches 14T and 18T described above) having a large aspect ratio or a surface having a three-dimensional shape. Accordingly, when the method described above is used, it is possible to form a carbon-based material layer with a desired thickness even on a surface, such as, a deep surface or a surface with a large aspect ratio, on which uniform deposition is difficult by the conventional method. Accordingly, even wirings having a complex surface shape may be formed so as not to generate a large electrical resistance.

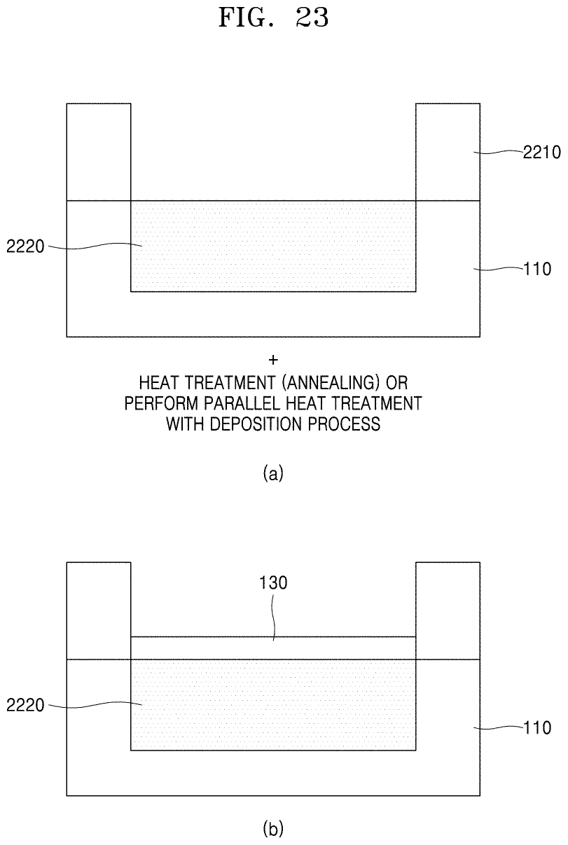

As shown in FIG. 23, by forming an upper layer 2210 on the lower layer 110, a region in which the ion implantation layer 2220 of the lower layer 110 is formed may be limited. The upper layer 2210 may correspond to the second substrate 1840 of FIG. 18.

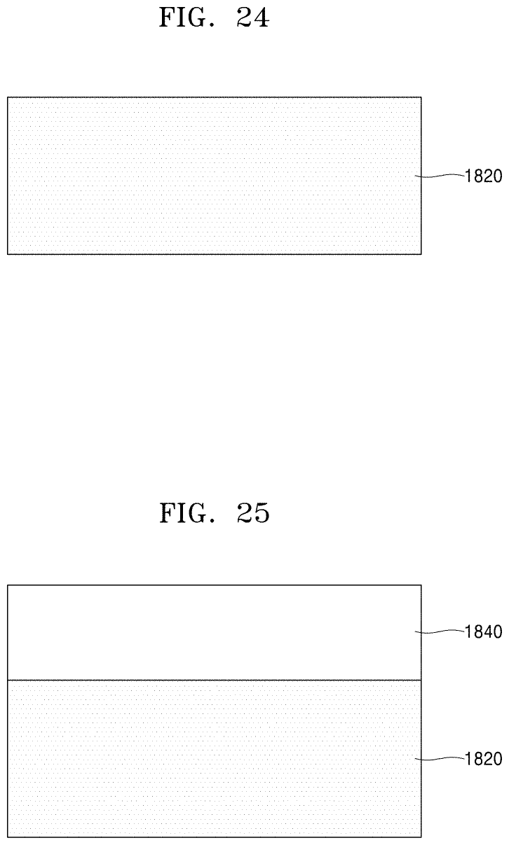

FIGS. 24 to 28 show a method of manufacturing a layer structure according to another embodiment.

First, as shown in FIG. 24, the first material C1 described with reference to FIGS. 22A and 22B is ion implanted into an entire area of the first substrate 1820. In this case, the first substrate 1820 may be an ion implantation layer.

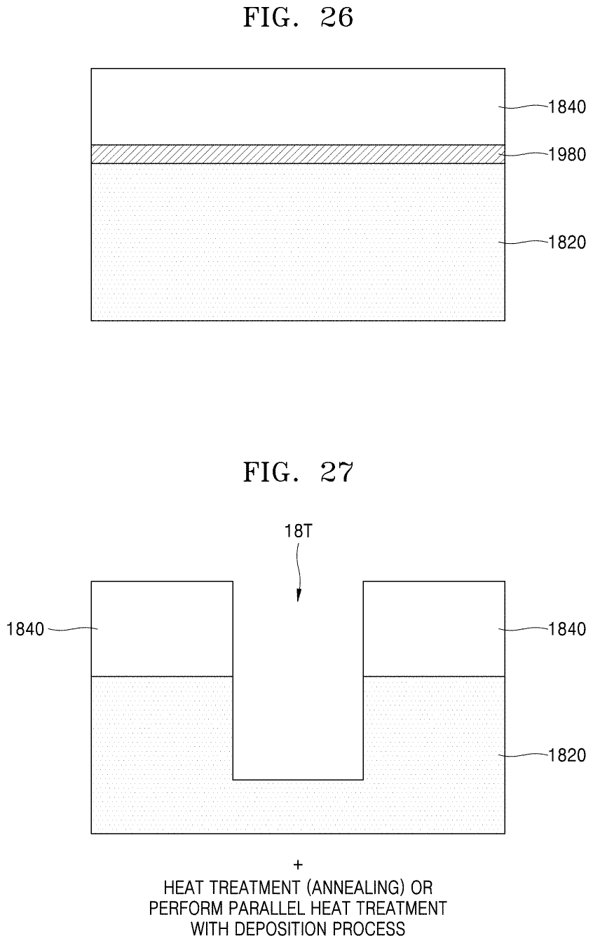

Next, as shown in FIG. 25, the second substrate 1840 is formed on the first substrate 1820. In an example embodiment, as shown in FIG. 26, a diffusion barrier layer 1980 may further be formed between the first substrate 1820 and the second substrate 1840.

After the second substrate 1840 is formed, as shown in FIG. 27, a trench 18T is formed in the first and second substrates 1820 and 1840 that are sequentially stacked. The trench 18T may be formed by applying a photolithography process of a semiconductor manufacturing process. The trench 18T penetrates through the second substrate 1840 and may be formed to a given depth downward from an upper surface of the first substrate 1820. In an example embodiment, after the trench 18T is formed, a heat treatment (annealing) process may be performed on a resultant product in which the trench 18T is formed. In an example embodiment, a heat treatment process and a deposition process may be performed together on the resultant product in which the trench 18T is formed. The heat treatment process and the deposition process may be the same as those described in the manufacturing method described with reference to FIGS. 22A to 22E.

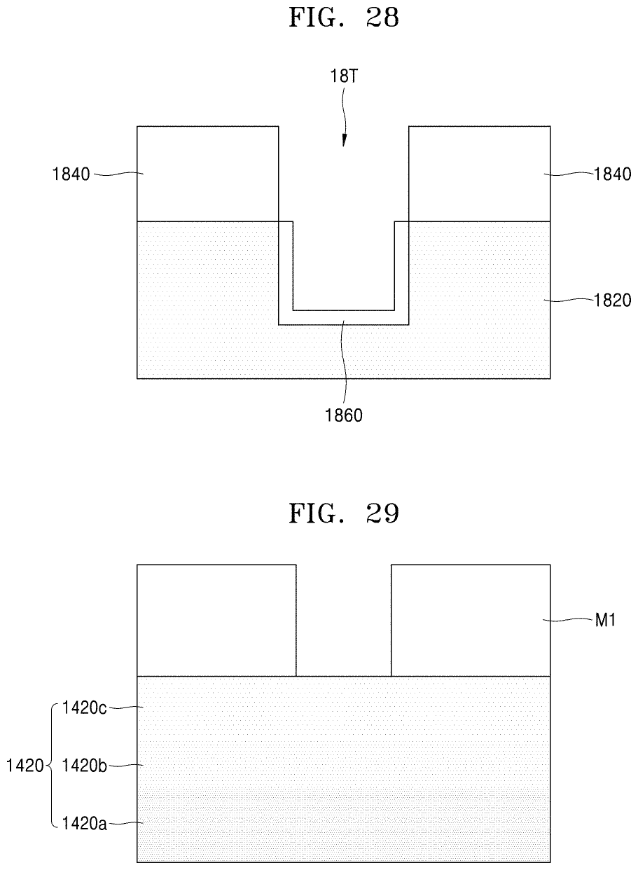

Accordingly, as shown in FIG. 28, a carbon-based material layer 1860 is formed on the bottom of the trench 18T and an inner surface of the trench 18T of the first substrate 1820. By adjusting a condition of the heat treatment process or the deposition process, a portion of the trench 18T or an entire trench 18T may be filled with the carbon-based material layer 1860. In one example, when the carbon-based material layer 1860 is formed by applying a heat treatment process with respect to a resultant product in which the trench 18T is formed, the heat treatment process may be performed under any one of a condition that the carbon-based material layer 1860 is formed in the form of coating the inner surface of the trench 18T or a condition that the carbon-based material layer 1860 fills at least a portion of the trench 18T. In one example, when the carbon-based material layer 1860 is formed by applying a heat treatment process and a deposition process to the resultant product in which the trench 18T is formed, the heat treatment process and the deposition process may be performed under any one of a condition that the carbon-based material layer 1860 is formed in the form of coating the inner surface of the trench 18T or a condition that the carbon-based material layer 1860 fills at least a portion of the trench 18T.

FIGS. 29 to 31 show a method of manufacturing a layer structure including a carbon-based material according to another embodiment.

Referring to FIG. 29, first to third ion implantation layers 1420a, 1420b, and 1420c having different ion implantation concentrations are sequentially formed on a substrate 1420. In an example, the first to third ion implantation layers 1420a, 1420b, and 1420c may be formed by ion-implanting the first material C1 described with reference to FIGS. 22A and 22B at different concentrations. The entire substrate 1420 may be filled with the first to third ion implantation layers 1420a, 1420b, and 1420c, but is not limited thereto.

After the first to third ion implantation layers 1420a, 1420b, and 1420c are formed, an etch mask M1 that defines a region in which a trench is formed is formed on the substrate 1420. The mask M1 may be an insulating layer or a photoresist layer.

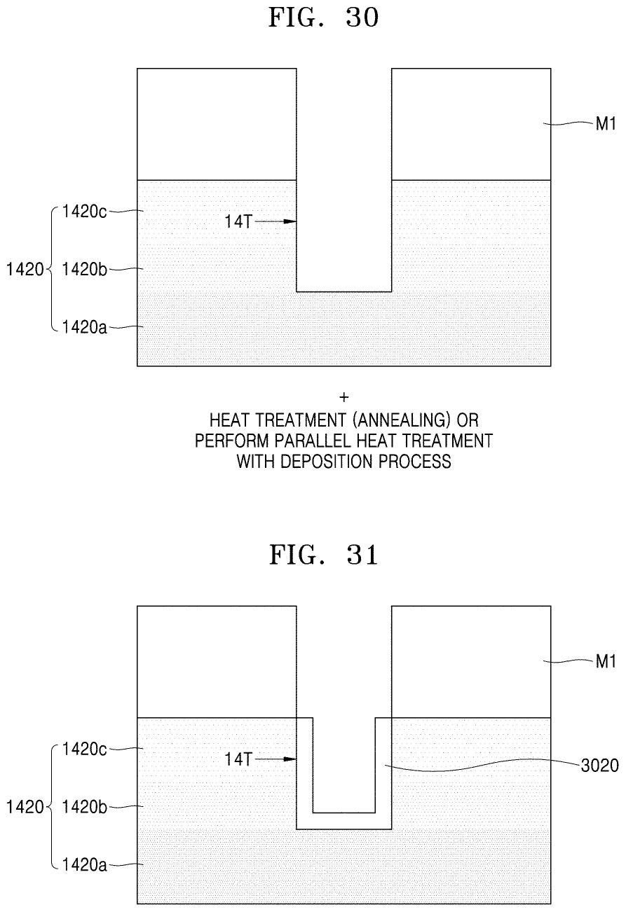

Next, as shown in FIG. 30, a desired and/or alternatively predetermined region of the substrate 1420 defined and exposed by the mask M1 is etched. The etching may be performed until the first ion implantation layer 1420a is exposed penetrating through the third and second ion implantation layers 1420c and 1420b. In this way, a trench 14T is formed in the substrate 1420. After the trench 14T is formed, a heat treatment (annealing) process is performed on the resultant product or a deposition process is performed together with the heat treatment process. The heat treatment process and deposition process may be the same as described with reference to FIG. 22D, but may be different. As a result of the heat treatment process or the heat treatment process and the deposition process, as shown in FIG. 31, a carbon-based material layer 3020 is formed on bottom and inner surfaces of the trench 14T. By controlling a condition of the heat treatment process and/or the deposition process, a part or all of the trench 14T may be filled with the carbon-based material layer 3020.

On the other hand, in the manufacturing method described above, in the process of forming a carbon-based material layers (e.g., 1860 and 3020) in a trenches 14T and 18T by using the heat treatment process or by using the heat treatment process and the deposition process together, silicon carbide (SiC) may be formed under the carbon-based material layers 1860 and 3020. Accordingly, when the lower layer is a silicon layer, a layer under the trenches 14T and 18T may have a stacked structure including a silicon layer/SiC/carbon-based material layer.

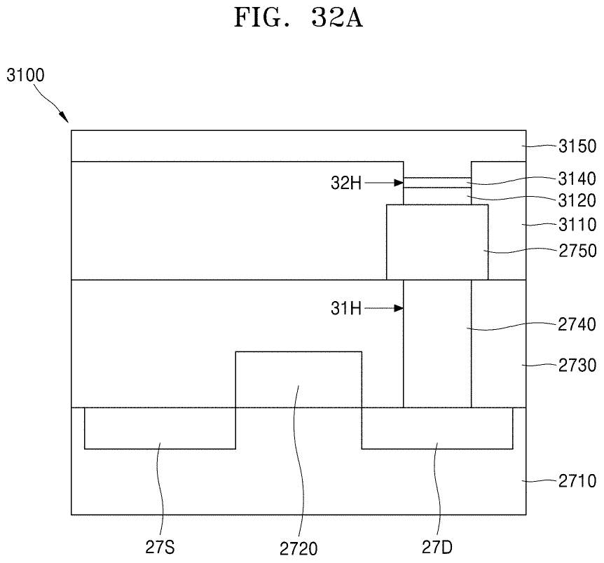

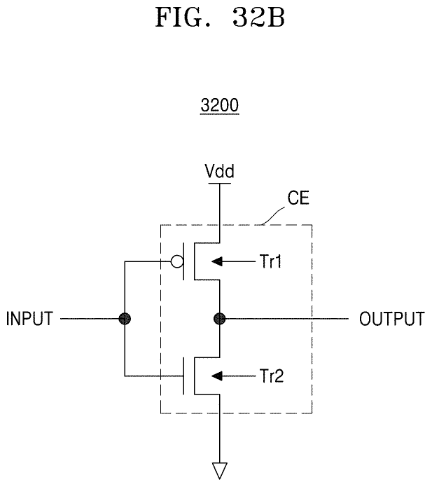

FIG. 32A shows a memory device 3100 having a layer structure including a carbon-based material according to an example embodiment.

Referring to FIG. 32A, the memory device 3100 may include a substrate 2710, first and second doped regions 27S and 27D formed on the substrate 2710, a gate stack 2720 provided on the substrate 2710 between the first and second doped regions 27S and 27D, and a data storage element 2750 connected to the second doped region 27D. The substrate 2710, the first and second doped regions 27S and 27D, and the gate stack 2720 may form a field effect transistor that controls a flow of electrical signals.

The substrate 2710 may include a semiconductor substrate doped with at least a first type impurity, and the first and second doped regions 27S and 27D may be provided on the semiconductor substrate. The substrate 2710 may be a P-type semiconductor substrate or an N-type semiconductor substrate doped with a P-type or N-type conductive impurity as the first type impurity. A non-semiconductor layer may further be provided under the semiconductor substrate. In an example, the non-semiconductor layer may include an insulating layer. The first and second doped regions 27S and 27D may be regions doped with a second type impurity. The second type impurity may be an impurity opposite to the first type impurity. For example, when the first type impurity is a P-type conductive impurity, the second type impurity may be an N-type conductive impurity. One of the first and second doped regions 27S and 27D may be a source region, and the other may be a drain region. The gate stack 2720 is arranged on the substrate 2710 between the first and second doped regions 27S and 27D. The gate stack 2720 may include a gate insulating layer and a gate electrode that are sequentially stacked. A first interlayer insulating layer 2730 covering the first and second doped regions 27S and 27D and the gate stack 2720 is formed on the substrate 2710. The first interlayer insulating layer 2730 includes a first via hole 31H exposing a portion of the second doped region 27D. A portion of the second doped region 27D may be exposed through the first via hole 31H. The first via hole 31H is filled with a conductive plug 2740.

The data storage element 2750 may be provided on the first interlayer insulating layer 2730, cover an upper surface of the conductive plug 2740, and may be in direct contact with the upper surface of the conductive plug 2740. The data storage element 2750 may include memory cells arranged in storage nodes of various memory devices. For example, the data storage element 2750 may include one of a memory cell arranged in one of a storage node of DRAM, a storage node of FRAM, a storage node of SRAM, a storage node of MRAM, and a storage node of PRAM, and is not limited thereto. The memory cell may include a configuration capable of storing data ‘1’ or ‘0’. For example, the memory cell may include a capacitor or a magnetic tunnel junction (MTJ).

A second interlayer insulating layer 3110 covering the data storage element 2750 may be provided on the first interlayer insulating layer 2730. A second via hole 32H may be provided in the second interlayer insulating layer 3110 to expose a portion of the data storage element 2750. A portion of an upper surface of the data storage element 2750 may be exposed through the second via hole 32H. For example, the upper surface of the data storage element 2750 exposed through the second via hole 32H may be an upper surface of a capacitor.

The second via hole 32H is filled with an ion implantation layer 3120, and a carbon-based material layer 3140 and a conductive layer 3150 that are sequentially stacked. In other words, the ion implantation layer 3120 and the carbon-based material layer 3140 are sequentially stacked on the bottom of the second via hole 32H, that is, the upper surface of the data storage element 2750 exposed through the second via hole 32H to fill a portion of the second via hole 32H and the rest of the second via hole 32H is filled with the conductive layer 3150. The ion implantation layer 3120 may be one of the aforementioned ion implantation layers, for example, the ion implantation layer 120 of FIG. 1. The carbon-based material layer 3140 may be one of the aforementioned carbon-based material layers, for example, the carbon-based material layer 130 of FIG. 1 or may include the carbon-based material layer 130 of FIG. 1. In one example, the carbon-based material layer 3140 may be extended between an inner surface of the second via hole 32H and the conductive layer 3150.

The conductive layer 3150 may fill up the second via hole 32H and be extended on the second interlayer insulating layer 3110. In one example, the conductive layer 3150 may act as a bit line and be provided in a line shape on the second interlayer insulating layer 3110. The conductive layer 3150 may be connected to the data storage element 2750 through one of the aforementioned layer structures. Accordingly, the resistance between the conductive layer 3150 and the data storage element 2750 may be lower than when the conductive layer 3150 and the data storage element 2750 are directly contacted.

FIG. 32B is a circuit diagram of a complementary metal-oxide semiconductor (CMOS) inverter 3200 according to an embodiment.

The CMOS inverter 3200 includes a CMOS transistor CE. The CMOS transistor CE includes a PMOS transistor Tr1 and an NMOS transistor Tr2 connected between a power terminal Vdd and a ground terminal. The first transistor Tr1 and the second transistor Tr2 may include a layer structure according to one of the embodiments described above. For example, one of the first transistor Tr1 and second transistor Tr2 may include a structure like the memory device 3100 described in FIG. 32A, except the data storage element 2750 may be omitted.

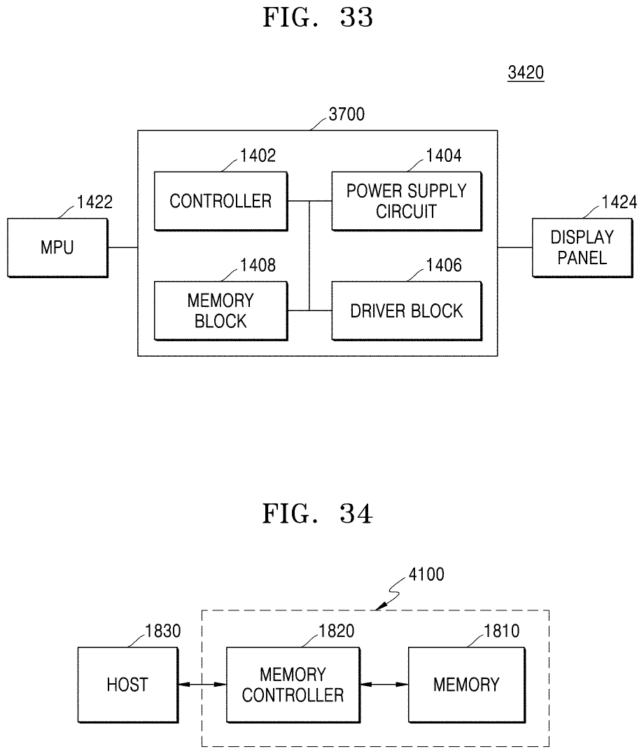

FIG. 33 is a schematic block diagram of a display driver IC (DDI) 3700 and a display device 3420 including the DDI 3700 according to an example embodiment.

Referring to FIG. 33, the DDI 3700 includes a controller 1402, a power supply circuit 1404, a driver block 1406, and a memory block 1408. The controller 1402 receives and decodes a command applied from a main processing unit (MPU) 1422, and controls each block of the DDI 3700 to implement an operation according to the command. The power supply circuit unit 1404 generates a driving voltage in response to the control of the controller 1402. The driver block 1406 drives a display panel 1424 using the driving voltage generated by the power supply circuit unit 1404 in response to the control of the controller 1402. The display panel 1424 may be a liquid crystal display panel or a plasma display panel, but is not limited thereto, and may be any other known flat panel display panel. The memory block 1408 is a block for temporarily storing commands input to the controller 1402 or control signals output from the controller 1402 or for storing necessary data, and may include a memory, such as RAM, ROM, etc. The memory block 1408 may include an electronic device according to an example embodiment described above.

FIG. 34 is a block diagram illustrating an electronic system 4100 according to an example embodiment.

The electronic system 4100 includes a memory 1810 and a memory controller 1820. The memory controller 1820 may control the memory 1810 to read data from and/or write data to the memory 1810 in response to a request from a host 1830. At least one of the memory 1810 and the memory controller 1820 may include the electronic device according to an example embodiment described above.

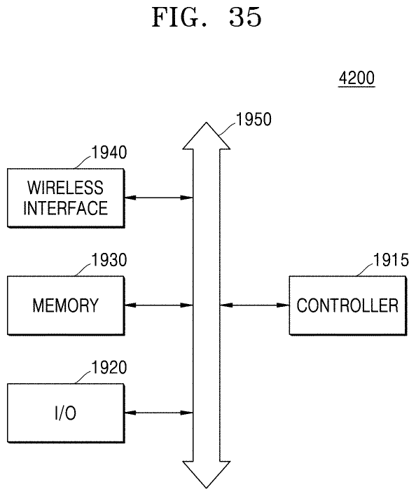

FIG. 35 is a block diagram of an electronic system 4200 according to an example embodiment.

The electronic system 4200 may configure a wireless communication device or a device capable of transmitting and/or receiving information in a wireless environment. The electronic system 4200 includes a controller 1915, an input/output (I/O) device 1920, a memory 1930, and a wireless interface 1940, and each of which is interconnected through a bus 1950.

The controller 1910 may include at least one of a microprocessor, a digital signal processor, or a processing device similar thereto. The I/O device 1920 may include at least one of a keypad, a keyboard, and a display. The memory 1930 may be used to store instructions executed by controller 1910. For example, the memory 1930 may be used to store user data. The electronic system 4200 may use the wireless interface 1940 to transmit/receive data over a wireless communication network. The wireless interface 1940 may include an antenna and/or a wireless transceiver. In some embodiments, the electronic system 4200 may be used in a communication interface protocol of a variety of communication systems, for example, code division multiple access (CDMA), global system for mobile communications (GSM), north American digital cellular (NADC), extended-time division multiple access (E-TDMA), and/or wide band code division multiple access (WCDMA). The electronic system 4200, as a memory device, may include the electronic device according to the embodiment described above.

An electronic device including a layer structure according to an example embodiment may exhibit high electrical performance with an ultrasmall structure, and thus, may be applied to an integrated circuit device, and may realize miniaturization, low power, and high performance.

In manufacturing the layer structure including the disclosed carbon-based material, after carbon is implanted in advance into a region where a wiring is to be formed, a heat treatment process is applied as a subsequent process, or a deposition process, such as CVD is applied together with the heat treatment process. With this application, graphene may be uniformly formed even in a deep part of a complicated pattern having a depth (e.g., a pattern having a deep trench), thereby limiting and/or preventing an increase in resistance of a complicated wiring having a depth. Accordingly, a sufficient resistance margin may be secured even when the size of the wiring becomes smaller according to the increase in the degree of integration, which may ensure a stable operation and high-speed operation of the electronic device.

In addition, the disclosed layer structure may be utilized as a diffusion barrier layer, a liner, etc. depending on an applied position.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A layer structure comprising:
a lower layer;
an ion implantation layer in the lower layer; and
a carbon-based material layer on the ion implantation layer,
wherein the ion implantation layer includes carbon.

2. The layer structure of claim 1, wherein
the ion implantation layer includes a trench, and
the carbon-based material layer is in the trench.

3. The layer structure of claim 2, wherein an ion implantation concentration of the ion implantation layer is uniform in an entirety of the ion implantation layer.

4. The layer structure of claim 2, wherein the ion implantation layer has an ion implantation concentration gradient in a given direction of the ion implantation layer.

5. The layer structure of claim 4, wherein the ion implantation layer includes a plurality of layers that are sequentially stacked and have different ion implantation concentrations from each other.

6. The layer structure of claim 1, further comprising:
an upper layer on a portion of the lower layer around the ion implantation layer.

7. The layer structure of claim 6, further comprising:
a barrier layer between the lower layer and the upper layer around the ion implantation layer.

8. The layer structure of claim 1, wherein the carbon-based material layer includes a heteromaterial and carbon.

9. The layer structure of claim 8, wherein the heteromaterial includes nitrogen, boron, or both nitrogen and boron.

10. The layer structure of claim 8, wherein the carbon-based material layer is a carbon compound layer including the heteromaterial.

11. The layer structure of claim 1, wherein the carbon-based material layer includes a graphene layer, a layered graphene layer, an amorphous carbon layer, or a nanocrystalline graphene layer.

12. An electronic device comprising:
a data storage element;
a transistor connected to a first side of the date storage element; and
a conductive layer connected to a second side of the data storage element through the layer structure of claim 1.

13. A method of manufacturing a layer structure, the method comprising:
forming an ion implantation layer including carbon in a lower layer;
forming an upper layer covering the ion implantation layer on the lower layer;
exposing the ion implantation layer by removing a portion of the upper layer;
forming a trench in an exposed portion of the ion implantation layer;
forming a carbon-based material layer on the ion implantation layer in the trench by performing a heat treatment process on the lower layer in which the ion implantation layer is formed,
wherein the heat treatment process includes one of forming a coating of the carbon-based material layer on an inner surface of the trench and filling at least a portion of the trench with the carbon-based material layer.

14. The method of claim 13, wherein
the forming the upper layer covering the ion implantation layer includes forming a diffusion barrier layer covering the ion implantation layer and forming the upper layer on the diffusion barrier layer, and
the exposing the ion implantation layer includes sequentially removing a portion of the upper layer and the diffusion barrier layer thereunder.

15. The method of claim 13, wherein the forming the ion implantation layer includes:
forming the upper layer on the lower layer, the upper layer defining a region of the lower layer; and
forming the ion implantation layer by implanting carbon into the region of the lower layer defined by the upper layer.

16. The method of claim 15, wherein the forming the upper layer forms a trench in the region of the lower layer prior to the forming the ion implantation layer.

17. The method of claim 13, wherein the forming the carbon-based material layer includes performing a deposition process together with the performing the heat treatment process on the lower layer.

18. The method of claim 17, wherein, the forming the trench to expose the ion implantation layer in the lower layer is performed before the carbon-based material layer is formed.

19. The method of claim 17, wherein, in the forming the carbon-based material layer,
the heat treatment process and the deposition process includes forming a coating of the carbon-based material layer on an inner surface of the trench, or
the heat treatment process and the deposition process includes filling at least a portion of the trench with the carbon-based material layer.

20. The method of claim 17, wherein
the deposition process includes supplying a carbon source to the lower layer, and
an amount of the carbon source supplied in the deposition process is less than an amount of the carbon source supplied when the carbon-based material layer is formed only by using the deposition process.
